(19) United States
(12) Patent Application Publication
(10) Pub. No.: US 2026/0367429 A1
(43) Pub. Date: Nov. 19, 2026

(54) SEMICONDUCTOR OPTICAL DEVICE

(71) Applicant: FURUKAWA ELECTRIC CO., LTD., Tokyo (JP)

(72) Inventors: Masaki WAKABA, Tokyo (JP); Tatsuya KIMOTO, Tokyo (JP)

(73) Assignee: FURUKAWA ELECTRIC CO., LTD., Tokyo (JP)

(21) Appl. No.: 19/742,997

(22) Filed: Jul. 15, 2026

Related U.S. Application Data
(63) Continuation of application No. PCT/JP2024/046462, filed on Dec. 27, 2024.

(30) Foreign Application Priority Data
Feb. 8, 2024 (JP) 2024-018172

(51) Int. Cl. G02F 1/017; H01S 5/20

(52) U.S. Cl. CPC G02F 1/017; H01S 5/20

(57) ABSTRACT

A semiconductor optical device includes: a substrate including an insulated region on a main surface thereof; an n-type semiconductor positioned on the insulated region; an active region, on the insulated region, positioned adjacent to the n-type semiconductor in a first direction along the main surface, the active region including a well layer and a barrier layer alternatively arranged in the first direction; a p-type semiconductor, on the insulated region, positioned adjacent to the active region on an opposite side of the n-type semiconductor in the first direction; an n-side electrode electrically connected to the n-type semiconductor; and a p-side electrode electrically connected to the p-type semiconductor.

This application is a continuation of International Application No. PCT/JP2024/046462, filed on Dec. 27, 2024 which claims the benefit of priority of the prior Japanese Patent Application No. 2024-018172, filed on Feb. 8, 2024, the entire contents of which are incorporated herein by reference.

### BACKGROUND

The present disclosure relates to a semiconductor optical device.

Semiconductor optical devices have been disclosed that have a waveguide structure which includes a silicon substrate with a SiO₂ layer formed thereon, includes an active region formed on the SiO₂ layer, and includes buried layers provided on both sides of the active layer (refer to Japanese Patent Application Laid-open No. 2015-15396 and Japanese Patent No. 6267584). In such a semiconductor optical device, one of the buried layers is subjected to first-type impurity doping, and the other buried layer is subjected to second-type impurity doping. In between the two buried layers, a structure is formed for injecting an electric current to the active region in the horizontal direction. In this type of semiconductor optical device, the light gets strongly confined inside the active layer. As a result, when the semiconductor optical device is a semiconductor laser device, the threshold electric current decreases. On the other hand, when the semiconductor optical device is an optical modulator, the modulation may be performed at a low applied voltage. Thus, it is believed that the characteristics of the semiconductor optical device may be enhanced.

### SUMMARY

In a semiconductor optical device, producing the quantum confined stark effect (QCSE) in the active region is beneficial from the perspective of enabling achieving enhancement in the performance. For example, when a semiconductor optical device is an optical modulator, the QCSE enables achieving enhancement in the speed of response to a modulation signal. However, in the semiconductor optical devices disclosed in Japanese Patent Application Laid-open No. 2015-15396 and Japanese Patent No. 6267584, since the layering direction of the quantum well layers and the barrier layers in the active region is substantially orthogonal to the direction of the electric field acting on the active region, the QCSE is not produced.

There is a need for a semiconductor optical device that enables a high degree of confinement of the light and enables effective production of the QSCE.

According to one aspect of the present disclosure, there is provided a semiconductor optical device including: a substrate including an insulated region on a main surface thereof; an n-type semiconductor positioned on the insulated region; an active region, on the insulated region, positioned adjacent to the n-type semiconductor in a first direction along the main surface, the active region including a well layer and a barrier layer alternatively arranged in the first direction; a p-type semiconductor, on the insulated region, positioned adjacent to the active region on an opposite side of the n-type semiconductor in the first direction; an n-side electrode electrically connected to the n-type semiconductor; and a p-side electrode electrically connected to the p-type semiconductor.

### BRIEF DESCRIPTION OF THE DRAWINGS

FIG. 1 is a schematic cross-sectional view of a semiconductor optical device according to a first embodiment;

FIG. 2 is a schematic top view of the semiconductor optical device according to the first embodiment;

FIGS. 3A to 3D are explanatory diagrams for explaining a manufacturing method for the semiconductor optical device according to the first embodiment;

FIGS. 4A to 4D are explanatory diagrams for explaining the manufacturing method for the semiconductor optical device according to the first embodiment;

FIG. 5 is a schematic cross-sectional view of a semiconductor optical device according to a second embodiment; and

FIG. 6 is a schematic top view of the semiconductor optical device according to the second embodiment.

### DETAILED DESCRIPTION

Exemplary embodiments are described below with reference to the accompanying drawings. However, the present disclosure is not limited by the embodiments described below. In the drawings, identical or corresponding constituent elements are referred to by the same reference numerals, and the same explanation is not repeated. Meanwhile, the drawings are schematic in nature, and it needs to be noted that the relationship among the dimensions of the constituent elements or the proportion of the constituent elements may be different than the actual situation. Among the drawings too, sometimes the relationship among the dimensions and the proportion may be different. Moreover, in the drawings, sometimes the directions are illustrated using the XYZ Cartesian coordinate system.

### First Embodiment

### Configuration of Semiconductor Optical Device

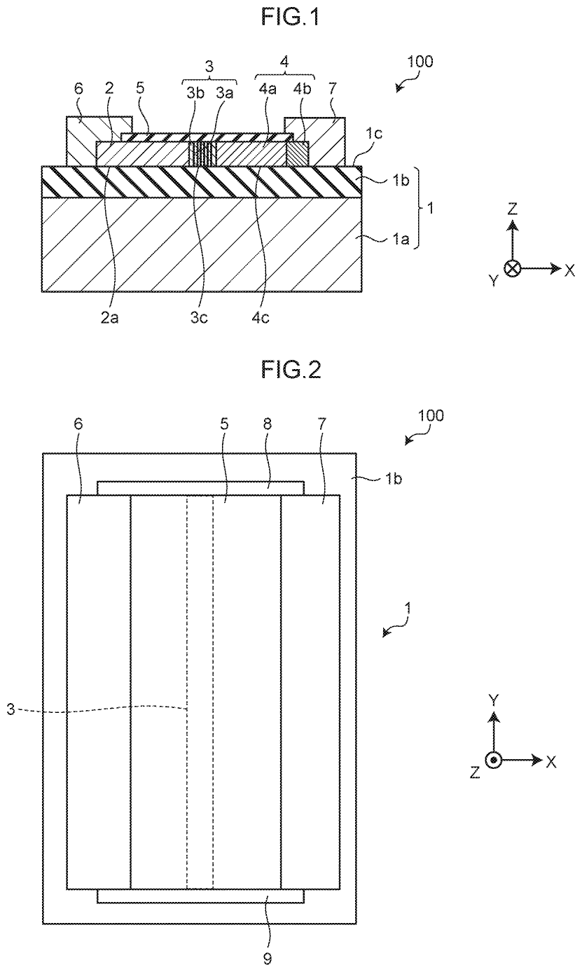

FIG. 1 is a schematic cross-sectional view of a semiconductor optical device according to a first embodiment. FIG. 2 is a top view of the semiconductor optical device according to the first embodiment. A semiconductor optical device 100 is configured to function as an electro-absorption (EA) modulator with respect to the light having a predetermined wavelength band. Although there is no particular restriction on the predetermined wavelength band, for example, the O band (1.26 μm to 1.36 μm) or the C-band (1.53 μm to 1.56 μm) serves as the predetermined wavelength band.

The semiconductor optical device 100 includes a substrate 1, an n-type semiconductor 2, an active region 3, a p-type semiconductor 4, a dielectric layer 5, an n-side electrode 6, a p-side electrode 7, and anti-reflection (AR) films 8 and 9.

The configuration of the substrate 1 is such that a substrate main body 1a, which is made of silicon (Si), and a silica (SiO₂) layer 1b, which is an insulated region, are layered in the Z direction (the upward direction). The silica layer 1b constitutes a main surface 1c of the substrate 1. The silica layer 1b is, for example, a native oxide layer. Alternatively, the silica layer 1b may be an oxide layer formed by performing oxidation of the main surface of the substrate main body 1a. The substrate 1 represents an example of a substrate that includes an insulated region on the main surface. Thus, the constituent element of the substrate main body is not limited to silicon. Moreover, the insulated region is not limited to silica. For example, the insulated region may be made of silicon nitride (SiNx).

The n-type semiconductor 2 is positioned on the silica layer 1b. The n-type semiconductor 2 has a layered shape expanding in the X and Y directions. The n-type semiconductor 2 comes into contact with the silica layer 1b on a contact surface 2a. The n-type semiconductor 2 is made of, for example, n-InP having the n-type as the conductivity type. Herein, InP stands for an InP-based semiconductor material, which represents an example of a semiconductor material having the zinc blende type structure. In the present written description, an n-type semiconductor may include, for example, silicon (Si), sulfur(S), or selenium (Se) as the n-type impurity.

The active region 3 is positioned on the silica layer 1b and adjacent to the n-type semiconductor 2 in the X direction along the main surface 1c. The active region 3 has a layered shape that has a relatively smaller layer thickness in the X direction and that expands in the Y direction. The active region 3 has a multiple quantum well structure in which a well layer 3a and a barrier layer 3b are alternately arranged in the X direction. The active region 3 comes into contact with the silica layer 1b on a contact surface 3c. The active region 3 is made of a semiconductor material having a higher refractive index than the refractive index of the n-type semiconductor 2. Meanwhile, the silica layer 1b, which is an insulated region, has a lower refractive index than the effective refractive index of the active region 3. The active region 3 is made of, for example, GaInAsP or AlGaInAs, and has a multiple quantum well structure. The composition of the active region 3 is set to make the semiconductor optical device 100 function as an EA modulator with respect to the light having a predetermined wavelength band. Herein, the X direction represents an example of a first direction.

The p-type semiconductor 4 is positioned on the silica layer 1b and adjacent to the active region 3 on the opposite side of the n-type semiconductor 2 in the X direction. The p-type semiconductor 4 has a layered shape expanding in the X and Y directions. The p-type semiconductor 4 includes a first layer 4a that is adjacent to the active region 3 in the X direction, and includes a second layer 4b that is adjacent to the first layer 4a in the X direction. The first layer 4a is made of a semiconductor material having a lower refractive index than the refractive index of the active region 3. The second layer 4b is made of a semiconductor layer that makes ohmic contact with the p-side electrode 7. The first layer 4a is made of, for example, p-InP having the p-type as the conductivity type. The second layer 4b is made of, for example, p-GaInAs. The second layer 4b is also called a contact layer. In the present written description, a p-type semiconductor may also include, for example, zinc (Zn) as the p-type impurity. The p-type semiconductor 4 comes into contact with the silica layer 1b on a contact surface 4c.

The dielectric layer 5 covers at least the active region 3 on the opposite side of the silica layer 1b in the Z direction, and also covers some portion of the n-type semiconductor 2 and some portion of the p-type semiconductor 4. The dielectric layer 5 may have a lower refractive index than the effective refractive index of the active region 3. The dielectric layer 5 is made of, for example, silica.

The n-side electrode 6 makes electrical contact with the n-type semiconductor 2. More particularly, the n-side electrode 6 makes ohmic contact with the n-type semiconductor 2 and, for example, includes gold or nickel.

The p-side electrode 7 makes electrical contact with the p-type semiconductor 4. More particularly, the p-side electrode 7 makes ohmic contact with the second layer 4b of the p-type semiconductor 4 and, for example, includes titanium, platinum, or gold.

The AR film 8 is formed to cover at least the end face of the active region 3 in the positive Y direction. In the first embodiment, the AR film 8 is formed to cover the end face of the n-type semiconductor 2 in the positive Y direction as well as to cover the end face of the p-type semiconductor 4 in the positive Y direction.

The AR film 9 is formed to cover at least the end face of the active region 3 in the negative Y direction. In the first embodiment, the AR film 9 is formed to cover the end face of the n-type semiconductor 2 in the negative Y direction as well as to cover the end face of the p-type semiconductor 4 in the negative Y direction.

In the semiconductor optical device 100 configured in the manner explained above, when a reverse-bias voltage is applied in between the n-side electrode 6 and the p-side electrode 7 and when a modulated voltage signal is applied; according to the modulated voltage signal, the state of the active region 3 switches between the state of absorbing the light having the wavelength band of 1.55 μm and the state of allowing passage of that light. As a result, the semiconductor optical device 100 functions as an EA modulator. Thus, in the semiconductor optical device 100, when the light having a predetermined wavelength is input from one of the end faces of the active region 3 in the Y direction, a modulated light that is obtained by modulation due to the modulated voltage signal gets output from the other end face.

At that time, in the semiconductor optical device 100, as a result of applying a reverse-bias voltage in between the n-side electrode 6 and the p-side electrode 7, it may be ensured that an electric field acts in the layering direction of the well layer 3a and the barrier layer 3b in the active region 3. Hence, the QCSE may be produced in an effective manner. As a result, the semiconductor optical device 100 functions as an EA modulator having a high speed of response to a modulation signal.

Moreover, in the semiconductor optical device 100, in the Z direction, the active region 3 is sandwiched between the silica layer 1b and the dielectric layer 5 that have low refractive indexes. Hence, the degree of confinement of the light is high. As a result, the semiconductor optical device 100 becomes able to perform modulation at a relatively lower applied voltage.

### Manufacturing Method for Semiconductor Optical Device

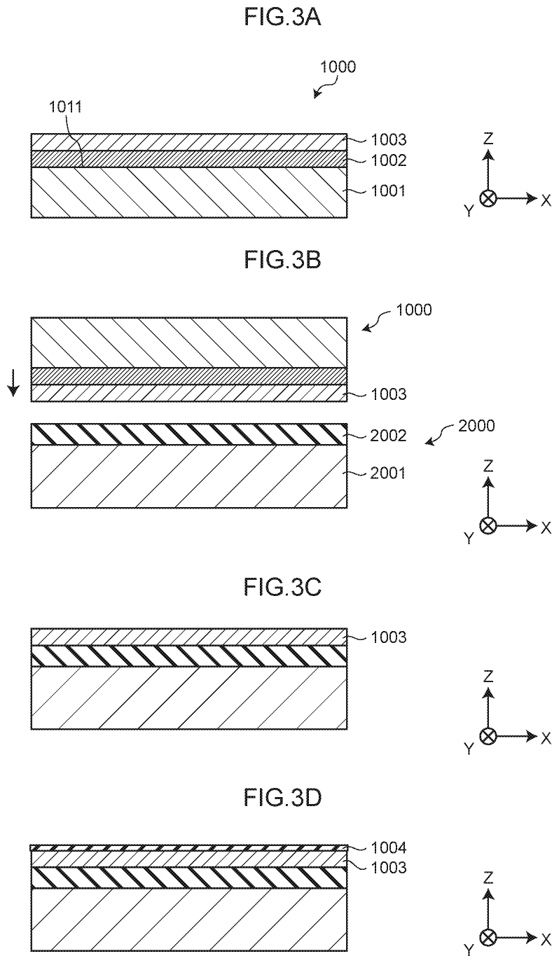

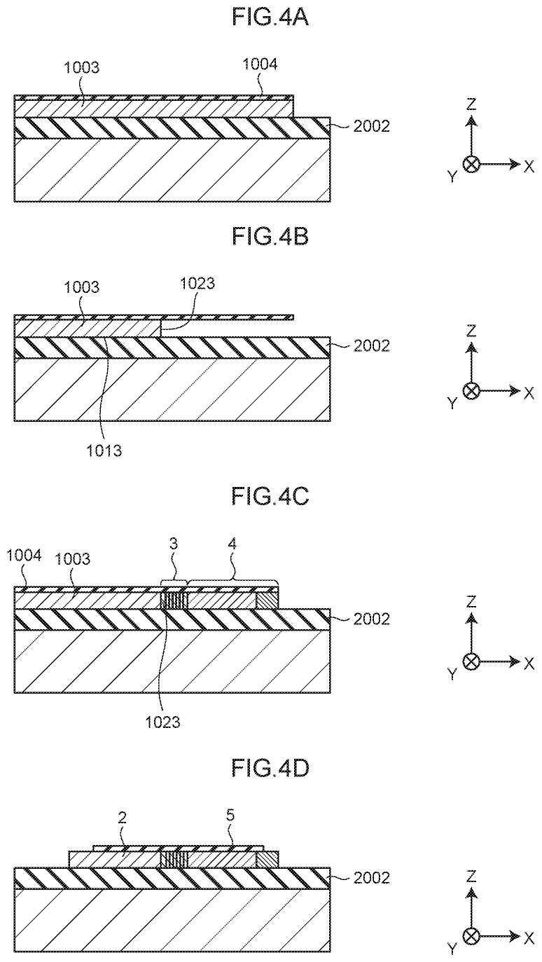

Explained below with reference to FIGS. 3A to 3D and FIGS. 4A to 4D is an exemplary manufacturing method for the semiconductor optical device 100 according to the first embodiment. Firstly, as illustrated in FIG. 3A, according to a crystal growth method such as the MOCVD method (MOCVD stands for Metal Organic Chemical Vapor Deposition), on a main surface 1011 of a substrate 1001 made of n-InP, a sacrificial layer 1002 and an n-type semiconductor layer 1003 are sequentially formed, and an epitaxial substrate 1000 is formed. The sacrificial layer 1002 is made of a semiconductor material, such as n-GaInAs or n-AlInAs, that has a higher etching rate with respect to a predetermined etchant than the etching rate of the n-type semiconductor layer 1003. The thickness of the sacrificial layer 1002 is, for example, equal to or greater than a few hundreds of nanometers, and is desirably equal to about 1000 nm. The n-type semiconductor layer 1003 serves as the n-type semiconductor 2 in the semiconductor optical device 100. The thickness of the n-type semiconductor layer 1003 is, for example, equal to about 200 nm.

In the substrate 1001, it is desirable that the main surface 1011 is a substantially (011) plane. That is, the main surface 1011 either may be the (011) plane or may be inclined with respect to the (011) plane by about a few degrees. However, it is more desirable that the main surface 1011 is inclined with respect to the (011) plane by only 2° toward the (111) B plane. The reason for that is explained later.

Subsequently, as illustrated in FIG. 3B, a substrate 2000 is provided that is configured by layering a substrate main body 2001, which is made of silicon, and a silica layer 2002; and the substrate 2000, the silica layer 2002, and the n-type semiconductor layer 1003 of the epitaxial substrate 1000 are bonded to form a bonded substrate. The bonding may be achieved according to a known method. For example, after the O₂ plasma treatment is performed, the silica layer 2002 and the n-type semiconductor layer 1003 are joined and heat-sealed.

In the bonding process mentioned above, the surface flatness of the substrate 2000 and the surface flatness of the epitaxial substrate 10000 is of critical importance. When the main surface 1011 of the substrate 1001 is a substantially (011) plane, in order to have the suitable surface flatness for the bonding process, it is important to have an inclination with respect to the (011) plane toward the (111) B plane, and it is more preferable to have the inclination of about 2°.

Then, as illustrated in FIG. 3C, etching is performed, and the substrate 1001 and the sacrificial layer 1002 are removed from the bonded substrate. As a result, the n-type semiconductor layer 1003 becomes exposed on the surface.

Subsequently, as illustrated in FIG. 3D, according to the chemical vapor deposition (CVD) method, a dielectric layer 1004 is formed on the n-type semiconductor layer 1003. The dielectric layer 1004 serves as the dielectric layer 5 in the semiconductor optical device 100.

Then, as illustrated in FIG. 4A, photolithography and dry etching is performed to implement patterning of the dielectric layer 1004 and the n-type semiconductor layer 1003.

Subsequently, as illustrated in FIG. 4B, some portion of the n-type semiconductor layer 1003 is removed by performing wet etching using, for example, a chlorine-based etching solution. At that time, the silica layer 2002 and the dielectric layer 1004 do not get etched, and the dielectric layer 1004 remains intact in the shape resembling a canopy with respect to the n-type semiconductor layer 1003. Moreover, at that time, if the main surface 1011 of the substrate 1001 is a substantially (011) plane; since a growth surface 1013 of the n-type semiconductor layer 1003 which has undergone epitaxial growth on the main surface 1011 is also a substantially (011) plane, an etched surface 1023 of the n-type semiconductor layer 1003 becomes a substantially (100) plane. The growth surface 1013 serves as the contact surface 2a in the n-type semiconductor 2.

Then, as illustrated in FIG. 4C, according to a crystal growth method such as the MOCVD method, the active region 3 and the p-type semiconductor 4 are sequentially formed on the etched surface 1023 of the n-type semiconductor layer 1003. Meanwhile, even when a crystalline material falls on the silica layer 2002, it does not undergo crystal growth. Instead, for example, the crystalline material moves to the etched surface 1023 of the n-type semiconductor layer 1003 and then undergoes crystal growth. As a result, the active region 3 and the p-type semiconductor 4 grow along the silica layer 2002.

Then, as illustrated in FIG. 4D, photolithography and dry etching is performed so that the dielectric layer 1004 and the n-type semiconductor layer 1003 are formed into the shapes of the dielectric layer 5 and the n-type semiconductor 2, respectively.

Subsequently, the n-side electrode 6 and the p-side electrode 7 are formed. Then, known processing such as formation of cleavages, formation of the AR films 8 and 9, and cutting into device pieces are performed. That marks the completion of the manufacturing of the semiconductor optical device 100.

### Second Embodiment

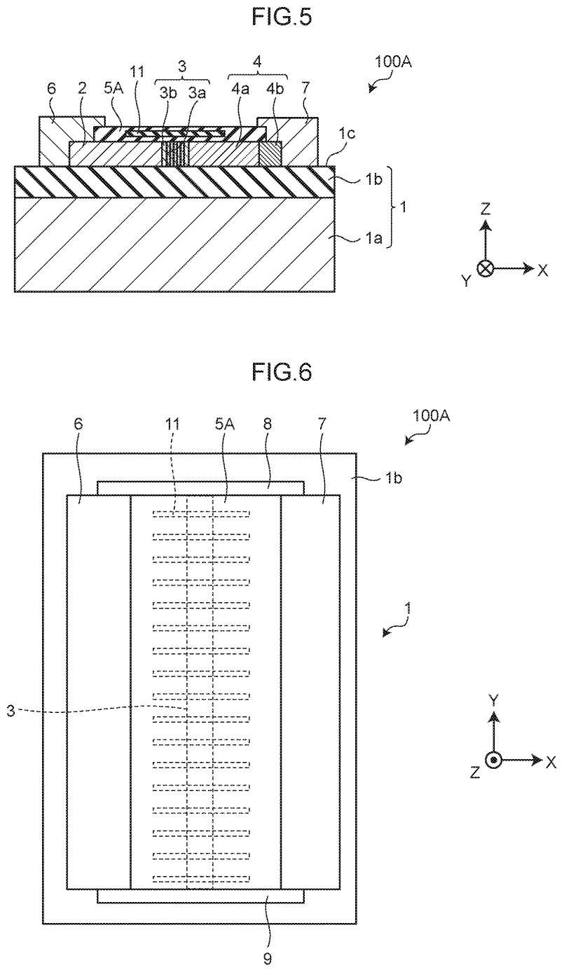

FIG. 5 is a schematic cross-sectional view of a semiconductor optical device according to a second embodiment. FIG. 6 is a top view of the semiconductor optical device according to the second embodiment. A semiconductor optical device 100A is configured to function as a DFB laser (DFB stands for Distributed Feed Back) that outputs a laser light having a predetermined wavelength.

The semiconductor optical device 100A is configured by substituting a dielectric layer 5A for the dielectric layer 5 in the semiconductor optical device 100 according to the first embodiment.

In the dielectric layer 5A, diffraction grating layers 11 are buried. The diffraction grating layers 11 are arranged above the active region 3 at predetermined intervals in the Y direction along the active region 3. The diffraction grating layers 11 are made of a dielectric material having a different refractive index than the refractive index of the dielectric layer 5A. For example, when the dielectric layer 5A is made of SiO₂, the diffraction grating layers 11 are made of SiNx.

In the semiconductor optical device 100A, the composition of the active region 3 is set to enable emission of a light having a predetermined wavelength.

In the semiconductor optical device 100A configured in the manner explained above, in between the n-side electrode 6 and the p-side electrode 7, when a bias voltage is applied and an electric current is injected, a laser light is output that has the wavelength corresponding to the spacing among the arranged diffraction grating layers 11. In this way, the semiconductor optical device 100A functions as a DFB laser device.

At that time, when a bias voltage is applied in between the n-side electrode 6 and the p-side electrode 7, it becomes possible to ensure that an electric field gets applied in the layering direction of the well layer 3a and the barrier layer 3b in the active region 3. Hence, the QCSE may be produced in an effective manner.

In the semiconductor optical device 100A, in the Z direction, the active region 3 is sandwiched between the silica layer 1b and the dielectric layer 5 that have low refractive indexes. Hence, the degree of confinement of the light is high. As a result, in the semiconductor optical device 100A, the threshold electric current is reduced. Moreover, since the active region 3 is sandwiched between the silica layer 1b, which is an insulator, and the dielectric layer 5, the electric current that is injected into the active region 3 does not easily leak into the portion other than the multiple quantum well structure. Hence, the injected electric current may be effectively utilized in laser oscillation.

Meanwhile, in the semiconductor optical device 100 according to the first embodiment, if the composition of the active region 3 is set to enable emission of a light having a predetermined wavelength and if the AR films 8 and 9 are substituted with reflecting mirrors that would constitute a laser oscillator; that semiconductor optical device may be configured to function as a Fabry-Perot semiconductor laser device.

In the embodiments described above, although the dielectric layer 5 is disposed, it may also be omitted. In that case, in the Z direction, the active region 3 gets sandwiched between the silica layer 1b and the air. In that case too, the degree of confinement of the light is high.

According to the present disclosure, it becomes possible to implement a semiconductor optical device that enables a high degree of confinement of the light and enables effective production of the QSCE.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A semiconductor optical device comprising:
a substrate including an insulated region on a main surface thereof;
an n-type semiconductor positioned on the insulated region;
an active region, on the insulated region, positioned adjacent to the n-type semiconductor in a first direction along the main surface, the active region including a well layer and a barrier layer alternatively arranged in the first direction;
a p-type semiconductor, on the insulated region, positioned adjacent to the active region on an opposite side of the n-type semiconductor in the first direction;
an n-side electrode electrically connected to the n-type semiconductor; and
a p-side electrode electrically connected to the p-type semiconductor.

2. The semiconductor optical device according to claim 1, wherein a refractive index of the insulated region is lower than an effective refractive index of the active region.

3. The semiconductor optical device according to claim 1, further comprising a dielectric layer covering at least the active region on an opposite side of the insulated region and having a lower refractive index than an effective refractive index of the active region.

4. The semiconductor optical device according to claim 1, wherein the semiconductor optical device is an electro-absorption modulator.

5. The semiconductor optical device according to claim 1, wherein the semiconductor optical device is a laser device.
